(19) United States
(12) Patent Application Publication
(10) Pub. No.: US 2008/0068074 A1
(43) Pub. Date: Mar. 20, 2008

(54) Efficient Narrow Band Amplification Using Linear Amplifier

(75) Inventor: Cary L. Delano, Los Altos, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Leadis Technology, Inc., Sunnyvale, CA (US)

(21) Appl. No.: 11/688,848

(22) Filed: Mar. 20, 2007

Related U.S. Application Data
(60) Provisional application No. 60/844,885, filed on Sep. 14, 2006.

(51) Int. Cl. H03F 3/38; H03F 3/04; H03F 3/68; H03G 3/20

(52) U.S. Cl. 330/10; 330/136

(57) ABSTRACT

An amplifier system having one or more signal paths. Each path includes a linear amplifier and a Class G Type amplifier. The linear amplifier receives an input signal bearing phase and amplitude information. The Class G Type amplifier receives an envelope signal which tracks the anticipated output signal, plus a DC offset. The output of the Class G Type amplifier is coupled to provide the VCC reference for the linear amplifier. High frequency performance and high efficiency are obtained.

### RELATED APPLICATION

This application is a continuation-in-part of U.S. Provisional Patent Application 60/844,885 entitled “Method and Apparatus for Efficient Narrow Band Amplification” filed Aug. 14, 2006 by Cary L. Delano, and claims benefit of that filing date to the maximum extent permissible. That application is incorporated herein by reference for all purposes.

### BACKGROUND OF THE INVENTION

1. Technical Field of the Invention

This invention relates generally to electronic amplifiers, and more specifically to an amplification technique which employs a Class G amplifier to modulate the supply in an envelope modulation system.

2. Background Art

Narrow-band, high-frequency, high-efficiency amplification is the subject of much research. The high frequencies involved limit the usability of techniques that work at lower frequencies. Some techniques involving class C, E, and F amplifiers have been used but these are usable only for phase modulation signaling. It is desirable to use both the phase and the amplitude in the modulation signaling to increase spectral efficiency, but in practice modulating the amplitude requires less efficient amplifiers.

Envelope modulation is a technique which has shown promise in the laboratory but which has not yet been made production worthy. Envelope modulation consists of two sub-techniques, illustrated in FIGS. 1 and 2, respectively.

FIG. 1 illustrates a known envelope modulation system 10 using nonlinear phase amplification. The system includes a phase amplifier, such as a Class C, E, or F amplifier, in the direct signal path. The phase amplifier receives an input signal VIN which includes at least the phase information to be imposed on the output signal VOUT of the phase amplifier. The input signal VIN may also include amplitude information, but any amplitude information will be ignored by the phase amplifier.

The system further includes a Class D amplifier which receives an input signal “Envelope of VIN” which gives the envelope of the VIN signal and thus includes the amplitude information to be imposed on the output of VOUT.

The output of the Class D amplifier switches and so is passed through an LC filter to reconstruct the analog signal that is desired to be applied to the VCC rail input of the phase amplifier. This produces the amplitude modulation on the VOUT signal.

The output of the VCC-modulated phase amplifier is passed to a matching network to drive an antenna. Since properly designed phase amplifiers and Class D amplifiers are efficient, the composite amplifier is efficient.

FIG. 2 illustrates a known envelope modulation system 20 using linear amplification. In this system, the linear amplifier passes both the amplitude and phase information of the RF input and attempts to faithfully produce this signal on its output. The Class D amplifier is driven with an input signal that is defined by the target envelope of the desired RF output signal (as produced by the linear amplifier) with some DC shift to keep the linear amplifier in its linear range. The added DC shift on the output of the LC filter should be high enough to avoid distortion in the linear amplifier. The adjustment of VCC keeps the linear amplifier operating in a power efficient region, and the Class D amplifier is inherently efficient, so the composite amplifier is efficient.

Such systems have not become practical in high volume production, because the envelope of the RF signals tends to be too fast for the Class D amplifiers to produce high efficiency or good linearity. The Class D amplifiers also produce extra, undesirable high frequency energy that can cause undesirable interference into the receive band. Also, it is difficult to correctly time align the envelope and phase signals in production amplifiers, due to the LC filter variations in the Class D amplifiers and other delays in the system. And finally, the LC filter requires valuable PCB space and is an expensive cost adder to the total bill of materials.

What is needed, then, is an improved envelope modulation system which employs Class G type amplifiers to obtain improved efficiency.

### BRIEF DESCRIPTION OF THE DRAWINGS

FIG. 1 shows a phase amplifier based envelope modulation system according to the prior art.

FIG. 2 shows a linear amplifier based envelope modulation system according to the prior art.

FIG. 3 shows an amplifier system according to one embodiment of this invention, using a phase amplifier.

FIG. 4 shows an amplifier system according to one embodiment of this invention, using a linear amplifier.

FIG. 5 shows an amplifier system according to one embodiment of this invention using phase amplifiers.

FIG. 6 shows an amplifier system according to another embodiment of this invention using linear amplifiers.

FIG. 7 shows a waveform analysis of a simulated operation of the circuit of FIG. 4.

FIG. 8 shows potential power rail combinations in a pair of Class G Type amplifiers.

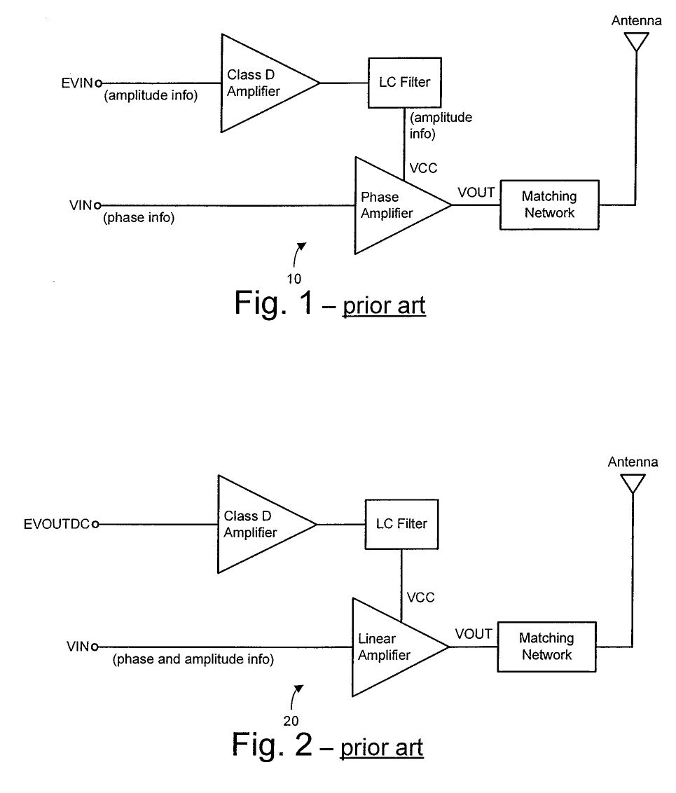

### DETAILED DESCRIPTION

The invention will be understood more fully from the detailed description given below and from the accompanying drawings of embodiments of the invention which, however, should not be taken to limit the invention to the specific embodiments described, but are for explanation and understanding only.

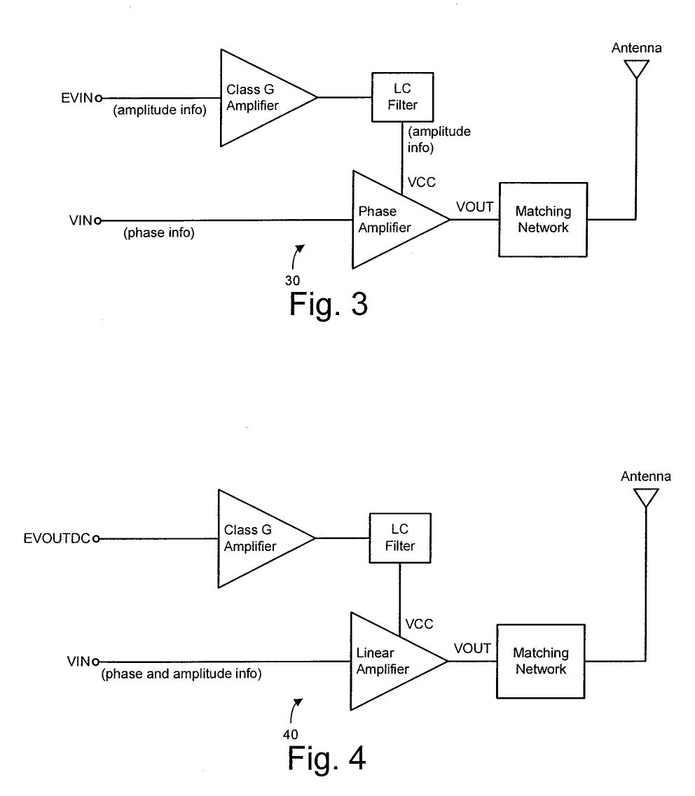

FIG. 3 illustrates a phase amplifier based envelope modulation system 30 according to one embodiment of this invention. A phase amplifier receives an RF input signal which includes at least the phase information to be imposed on the output signal VOUT of the phase amplifier. A Class G amplifier receives an envelope signal giving the envelope of the VIN signal. An optional LC filter is coupled between the output of the Class G amplifier and the VCC input of the phase amplifier. The RF output VOUT of the phase amplifier is fed to a matching network, which drives an antenna.

FIG. 4 illustrates a similar linear amplifier based envelope modulation system 40 according to another embodiment of this invention. A linear amplifier receives an RF input signal VIN which passes both the amplitude information and the phase information. A Class G amplifier receives an envelope signal giving the envelope of the desired VOUT signal plus a DC shift. An optional LC filter is coupled between the output of the Class G amplifier and the VCC input of the linear amplifier. The RF output VOUT of the linear amplifier is fed to a matching network, which drives an antenna.

In either embodiment, the system controls the amplitude of its supply with a Class G amplifier, which switches its output device between more than one power supply rail in order to increase power efficiency. Class G amplifiers are easier to make work at high frequencies than are the Class D amplifiers used in the prior art, and they don't produce significant amounts of out of band energy. While a Class D amplifier would require a large LC filter to remove out of band energy, the Class G amplifier can use a significantly smaller LC filter or even no LC filter. Having a smaller—or omitted—LC filter allows for better alignment of the envelope to the RF output signal. Since Class G amplifiers are efficient and the power supply of the linear amplifier is close to the envelope, the overall system is very power efficient.

In FIGS. 3 and 4, the amplifiers are shown as single ended, but one skilled in the art can easily convert this into a bridged configuration with a matching network, within the scope of this invention.

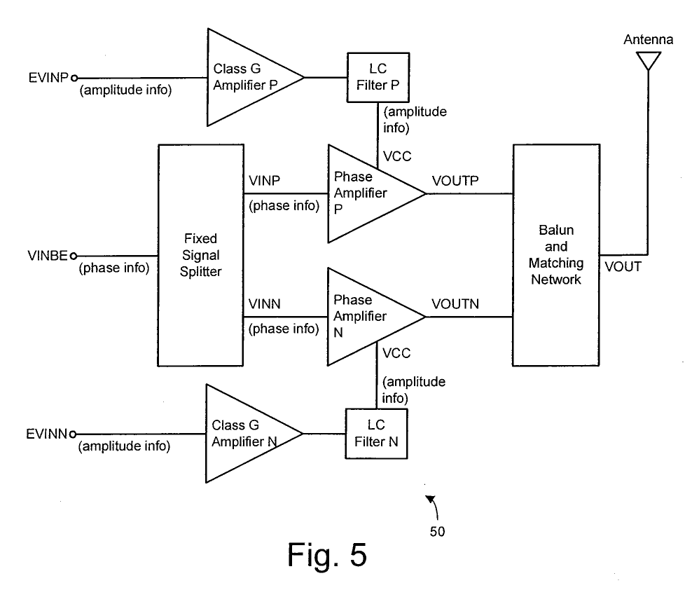

FIG. 5 illustrates an envelope modulation system 50 according to yet another embodiment of this invention. In this embodiment, the system is enhanced by splitting the RF signal path into two or more separate paths. This looks like bridging, but the gain of each path is not going to be fixed at an even split in the adjustable splitter as would have been done in a bridged configuration.

A fixed signal splitter receives the input signal VINBE which provides phase information to be imposed on the output signal, and splits it into a positive signal path input signal VINP and a negative signal path input signal VINN. (“P” and “N” may be understood to suggest “positive” and “negative” as a simplistic shorthand for distinguishing the two halves of the circuit.) A first Class G Amplifier P in the positive signal path receives an input signal EVINP which defines the envelope of the input signal VINBE except the gain. A second Class G Amplifier N in the negative signal path receives an input signal EVINN which defines the envelope of the input signal VINBE except the gain. The envelope signals EVINP and EVINP include amplitude information which is to be imposed on the output signal.

A first Phase Amplifier P receives the VINP signal, and its VCC is modulated by the Class G Amplifier P (after passing through an optional LC Filter P), to produce a positive signal path output signal VOUTP. A second Phase Amplifier N receives the VINN signal, and its VCC is modulated by the Class G Amplifier N (after passing through an optional LC Filter N), to produce a negative signal path output signal VOUTN.

A balun and matching network combines the VOUTP and VOUTN signals to produce the final output signal VOUT which is driven onto the antenna.

EVINP and EVINN are determined by the envelope of VINBE but then adjusted based on the target envelope amplitude in order to pass the RF signal envelope through more rail combinations, to increase power efficiency. Digital lookahead to give advance notice to the Class G circuitry may be used to control the transitioning of the Class G amplifiers in order to more cleanly and easily provide lookahead transitioning for the Class G amplifier rails.

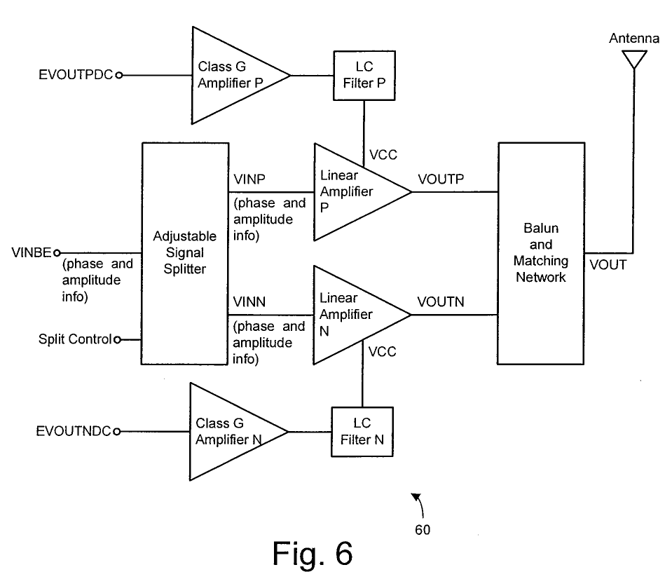

FIG. 6 illustrates an envelope modulation system 60 according to yet another embodiment of this invention. In this embodiment, too, the input signal is split into two signal paths.

An input signal VINBE is received by an adjustable signal splitter, and contains both the phase information and the amplitude information to be imposed on the output signal. The signal splitter splits VINBE according to a split control signal, to generate a positive signal path input signal VINP and a negative signal path input signal VINN. There are many ways to make adjustable splitters. In integrated circuit design, the adjustable splitter can be two separate gain stages where the gain to each linear amplifier is independently controllable. The adjustable signal splitter is adjusted based on the envelope amplitude in order to pass the RF signal envelope through more rail combinations to increase power efficiency.

The positive signal path input signal VINP is received by a first Linear Amplifier P which amplifies it to generate a positive path output signal VOUTP. The negative signal path input signal VINN is received by a second Linear Amplifier N which amplifies it to generate a negative path output signal VOUTN. A balun and matching network (which may be combined for both signal paths, as shown, or may be separately implemented in the two signal paths) combines these two output signals to produce the final output signal VOUT which it drives onto the antenna.

A first Class G Amplifier P receives a signal EVOUTPDC which gives the desired envelope of the VOUTP signal plus a DC shift, and produces a VCC reference for the Linear Amplifier P. Optionally, this VCC may first be passed through an LC Filter P. A second Class G Amplifier N receives a signal EVOUTNDC which gives the desired envelope of the VOUTN signal plus a DC shift, and produces a VCC reference for the Linear Amplifier N. Optionally, this VCC may first be passed through an LC Filter N.

Optionally, digital lookahead is used, by using the split control signal or one substantially similar to it, to control the transitioning of the Class G amplifiers. In digital RF modulation, it is common that the RF signal amplitude and envelope are digitally predictable. This can be used to more cleanly and easily provide lookahead transitioning for the Class G amplifier rails.

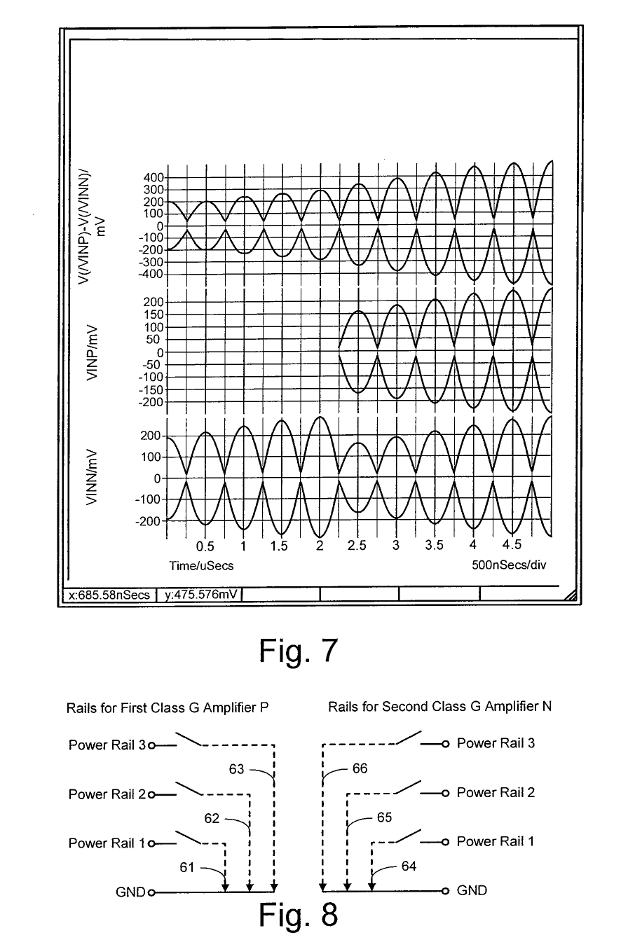

FIG. 7 is a waveform chart plotted by simulation software showing an example of the one transition of the adjustable splitter of the system of FIG. 6. In this example, the splitter makes the transition at an envelope (and RF) zero crossing to minimize the disturbance of adjusting the envelope. This is not required but it minimizes distortion. In this example, an input signal splitting associated with a single Class G rail transition is shown, for purposes of illustration. In this example, the input waveform VINBE is shown on the first line. It is an RF signal with increasing envelope amplitude. Initially, the splitter puts all of the signal to one side shown on the last line (labeled VINN). After a threshold is crossed, the splitter (approximately) evenly distributes the signal to the paths labeled VINP and VINN.

In the context of FIGS. 3-7, the term “Class G Type amplifier” is intended to mean any sort of amplifier which is “beyond Class D”, meaning that it is able to select between more than two power rails (including ground). Such an amplifier is taught in co-pending application ______ entitled “Class L Amplifier” filed ______ by Cary L. Delano. A Class D amplifier is not a Class G Type amplifier, because it selects between only two power rails. In some embodiments, the Class G amplifier could be replaced with some other rail-switching mechanism which is not an amplifier, such as a collection of switches coupled to multiple different rails.

FIG. 8 illustrates one possible set of rail combinations that are possible in Class G amplifiers of the systems of FIGS. 3-6. One example of how this can be done is disclosed in the co-pending application entitled “Class L Amplifier” cited above.

The first Class G Amplifier P may be powered by rail combination 61 (power rail 1 to ground), rail combination 62 (power rail 2 to ground), or rail combination 63 (power rail 3 to ground), and the second Class G Amplifier N may be powered by rail combination 64 (power rail 1 to ground), rail combination 65 (power rail 2 to ground), or rail combination 65 (power rail 3 to ground). Corresponding power rails at the two amplifiers may, but are not necessarily, at the same voltage level. In this example, the RF amplifier always used a GND bottom rail. That helps with RF amplifier design but it is not absolutely necessary; using a non-GND reference is possible within the scope of this invention, for example a combination of power rail 3 to power rail 1.

In one embodiment, for the smallest envelope (of VOUTP/N in FIG. 6), the adjustable input splitter would split the input signal so that the output signal envelope was entirely within the zone of rail combination 61. (In the context of FIG. 5, the target envelope of VOUTP/N would be selected in order to keep the output envelope entirely within the zone of rail combination 61.) Next, the envelope would grow into the zone of rail combination 62, then rail combination 63. After the zone of rail combination 63 was reached, the input splitter (or target envelope input) would pass further growths in the signal envelope to the zone of rail combination 64, where the signal consists of the zone 63 amplitude plus the zone 64 amplitude. Then, further signal growth would push into the zone of rail combination 65, and finally the zone of rail combination 66 (again, in combination with the amplitude of zone 63).

In other embodiments, other orderings are possible. For example, after zone 61 is exhausted, signal growth could be accommodated by using zone 64 (before zones 62 or 63). Then, it could use zone 62 with zone 64, then zone 62 with zone 65, followed by zone 63 with zone 65, then zone 63 with zone 66, and so forth.

In some embodiments, zones 61 and 62 may be used as subsets of zone 63, and zone 61 may be used as a subset of zone 62, and similarly for zones 64-66. Using the subset zones helps with efficiency, but is not required.

Note that FIG. 7 depicts a transition from using zone 61 to using zone 61 plus zone 64.

In some embodiments, the power rails are linearly spaced, such that power rails 1 and 2 are respectively 33.3% and 66.7% of the voltage of power rail 3. This yields six possible configurations: (1) zone 61 (33.3%), (2) zone 62 (66.7%), (3) zone 63 (100%), (4) zone 63 plus zone 64 (133.3%), (5) zone 63 plus zone 65 (166.7%), and (6) zone 63 plus zone 66 (200%).

In other embodiments, the zones are non-linearly spaced, in order to produce more rail combinations. For example, if power rails 1 and 2 are respectively 20% and 60% of the voltage of power rail 3, there are eight rail combinations: (1) zone 61 or zone 64 (20%), (2) zone 61 plus zone 64 (40%), (3) zone 62 or zone 65 (60%), (4) zone 62 plus zone 64 or zone 61 plus zone 65 (80%), (5) zone 63 or zone 66 (100%), (6) zone 63 plus zone 64 or zone 66 plus zone 61 or zone 62 plus zone 65 (120%), (7) zone 63 plus zone 65 or zone 66 plus zone 62 (160%), and (8) zone 63 plus zone 66 (200%). This can be advantageous, because the more power rails there are, and the more intelligently they are used, the higher the ultimate theoretical efficiency of the system becomes. Non-linearly spaced power rails can also be used to match the probability density function for the RF power transmission to better optimize average power dissipation. Matching the rails to the probability density function is useful in all cases such as in FIGS. 3 or 4 or in the expanded cases with added power rail combinations.

In another embodiment, the rails are adjusted based on signal level, such as by using digital lookahead or by inspecting the input signal. This allows the rails to be optimized to provide the highest efficiency for the current signal level.

The number of zones, and the voltage levels of the rails, given above are for illustration only, and are not intended to be an exhaustive listing. The invention may be practiced with a wide variety of Class G Type amplifier configurations.

In some embodiments, the signal can be broken into more than two paths with various phases, and can be recombined with a more complicated matching network. This will tend to further increase theoretical efficiency, but may add to cost and complexity of the matching network. For example, there may be four signal paths and three baluns; such a system would look like a double set of the circuitry of FIG. 3 or 4, with an additional balun combining the two sets into one RF output going to a single antenna. Odd numbers of paths are also possible. For example, if the phases are not 180 degrees apart, a combining matching network can still align the different path phases at the antenna.

The principles of this invention may also be applied to a sort of inverted system in which the linear amplifier or phase amplifier is on the supply side using P-type devices (e.g. PLDMOS, PMOS, etc.) and the amplitude modulation portion of the circuitry uses Class G Type amplifiers switching to lower rails. The principles of this invention may also be employed in power control of phase amplifiers, in which case the amplitude modulation in the power supply is simply a DC level to control the output power.

### Conclusion

When one component is said to be “adjacent” another component, it should not be interpreted to mean that there is absolutely nothing between the two components, only that they are in the order indicated.

The various features illustrated in the figures may be combined in many ways, and should not be interpreted as though limited to the specific embodiments in which they were explained and shown.

Those skilled in the art, having the benefit of this disclosure, will appreciate that many other variations from the foregoing description and drawings may be made within the scope of the present invention. Indeed, the invention is not limited to the details described above. Rather, it is the following claims including any amendments thereto that define the scope of the invention.

What is claimed is:

1. An amplifier system comprising:
(a) a first linear amplifier having,
an output coupled to provide a first amplified output signal,
a signal input coupled to receive a first input signal which provides phase and amplitude information for the first amplified output signal, and
a power supply input; and
(b) a first Class G Type amplifier having,
an input coupled to receive a first definition signal which tracks an envelope of the first amplified output signal, and
an output coupled to the power supply input of the first amplifier.

2. The amplifier system of claim 1 further comprising:
a filter coupled between the output of the first Class G Type amplifier and the power supply input of the first linear amplifier.

3. The amplifier system of claim 1 further comprising:
a matching network coupled to the output of the first linear amplifier to provide an output signal from the amplifier system for coupling to an antenna.

4. The amplifier system of claim 1 wherein the matching network comprises:
a balun.

5. The amplifier system of claim 1 further comprising:
(c) a second linear amplifier having,
an output coupled to provide a second amplified output signal,
a signal input coupled to receive a second input signal which provides phase and amplitude information for the second amplified output signal, and
a power supply input; and
(d) a second Class G Type amplifier having,
an input coupled to receive a second definition signal which tracks an envelope of the second amplified output signal, and
an output coupled to the power supply input of the second phase amplifier; and
(e) a signal splitter having,
an input coupled to receive a third input signal,
a first output for splitting the third input signal to produce the first input signal, and
a second output for splitting the third input signal to produce the second input signal; and
(f) a balun and matching network coupled to receive the first and second amplified output signals and to combine them into a combined output signal for coupling to an antenna.

6. The amplifier system of claim 5 further comprising:
a first filter coupled between the output of the first Class G Type amplifier and the power supply input of the first linear amplifier; and
a second filter coupled between the output of the second Class G Type amplifier and the power supply input of the second linear amplifier.

7. The amplifier system of claim 5 further comprising:
an adjustable splitter coupled to receive a third input signal and split it into the first and second input signals in response to a split control signal.

8. The amplifier system of claim 1 wherein the first Class G Type amplifier comprises:
a Class G amplifier.

9. An RF amplifier system for coupling to an antenna, the system comprising:
(a) two signal paths, each including,
a Class G Type amplifier having an input for receiving an envelope signal, and having an output,
a linear amplifier having a signal input, a voltage reference input coupled to the output of the Class G Type amplifier, and an output;
(b) a signal splitter having an input for receiving an input signal containing phase and amplitude information, and two outputs each coupled to the signal input of the linear amplifier of a respective one of the signal paths; and
(c) a balun and matching network having,
two inputs each coupled to the output of the linear amplifier of a respective one of the signal paths, and an output for coupling to the antenna.

10. The RF amplifier system of claim 9 wherein each signal path further includes:
an LC filter coupling the output of the Class G Type amplifier to the voltage reference input of the linear amplifier.

11. A method of driving an antenna with an output signal having phase information and amplitude information, wherein the method comprises:
receiving an input signal containing phase and amplitude information;
performing linear amplification on the input signal to generate a first output signal containing the phase information and the first amplitude information;
receiving a first envelope signal;
performing Class G Type amplification on the first envelope signal to generate a first voltage reference signal, the first voltage reference signal providing a power rail for use in the linear amplification; and
coupling the first output signal to the antenna.

12. The method of claim 11 further comprising:
filtering the voltage reference signal to provide the power rail.

13. The method of claim 11 further comprising:
splitting the input signal into a first input signal and a second input signal;
wherein the performing linear amplification on the input signal includes,
performing first linear amplification on the first input signal to generate the first output signal, and
performing second linear amplification on the second input signal to generate a second output signal;
receiving a second envelope signal;
performing Class G Type amplification on the second envelope signal to generate a second voltage reference signal, the second voltage reference signal providing a power rail for use in the second linear amplification; and
combining the first and second output signals to form the output signal.

14. The method of claim 13 further comprising:
filtering the first and second voltage reference signals.

15. The method of claim 13 further comprising:
adjusting the splitting in response to a split control signal.
